(19) United States
(12) Patent Application Publication
(10) Pub. No.: US 2010/0085086 A1
(43) Pub. Date: Apr. 8, 2010

(54) Digital Frequency Detector

(75) Inventors: Nikola Nedovic, San Jose, CA (US); Nestor Tzartzanis, Redwood City, CA (US); William W. Walker, Los Gatos, CA (US)

Correspondence Address: BAKER BOTTS L.L.P., 2001 ROSS AVENUE, SUITE 600, DALLAS, TX, 75201-2980, US

(73) Assignee: Fujitsu Limited, Kawasaki-shi (JP)

(21) Appl. No.: 12/510,211

(22) Filed: Jul. 27, 2009

Related U.S. Application Data
(60) Provisional application No. 61/084,435, filed on Jul. 29, 2008.

(51) Int. Cl. H03B 19/00

(52) U.S. Cl. 327/117

(57) ABSTRACT

In one embodiment, a method is described that includes receiving a first clock signal and a second clock signal; dividing the first clock signal by a value of n to generate a divided first clock signal; sampling the frequency detector the divided first clock signal with the second clock signal to generate a plurality of samples; generating a first adjustment signal if more than a predetermined number of consecutive samples in a set of consecutive samples have identical logical values; and generating a second adjustment signal if less than the predetermined number of consecutive samples in the set of consecutive samples have identical logical values.

### RELATED APPLICATION

This application claims the benefit, under 35 U.S.C. §119(e), of U.S. Provisional Patent Application No. 61/084,435, entitled Digital Frequency Detector, filed 29 Jul. 2008.

### TECHNICAL FIELD

The present disclosure relates generally to clock and data recovery (CDR) circuits.

### BACKGROUND

CDR circuits (or systems) are generally used to sample an incoming data signal, extract the clock from the incoming data signal, and retime the sampled data. A phase-locked loop (PLL) based CDR circuit is a conventional type of CDR circuit that utilizes negative feedback. A PLL circuit responds to both the frequency and the phase of a reference signal, automatically raising or lowering the frequency of a voltage-controlled oscillator (VCO) until it is matched to the reference signal in both frequency and phase. In simpler terms, a PLL compares the phases of two signals and produces an error signal which is proportional or otherwise dependent on the difference between the input phases. The error signal is then low-pass filtered by a loop filter and used to drive the VCO which creates an output clock frequency. The output clock frequency is fed through a frequency divider back to the input of the system, producing a negative feedback loop. If the output clock frequency drifts, the error signal will increase, driving the frequency in the opposite direction so as to reduce the error. Thus the circuit attempts to lock the frequency of the output clock to the frequency at the reference input. The dynamics of the loop are generally determined by the open loop gain and the location of open loop zeroes and poles (predominantly in the loop filter).

Conventional frequency detectors in CDR circuits and phase locked loops (PLL) typically operate in the analog domain. Even in the conventional frequency detectors that output digital signals, such as a Phase and Frequency Detector (PFD), these frequency detectors carry the phase information in the analog properties of the signal (e.g., pulse width).

### BRIEF DESCRIPTION OF THE DRAWINGS

FIG. 1 illustrates an example CDR circuit.

FIG. 2 illustrates example states of a finite state machine.

FIG. 3 illustrates an example frequency acquisition circuit.

FIG. 4 illustrates example frequency output of a voltage-controlled oscillator as a function of an analog control voltage setting and a selected frequency gain curve.

FIG. 5 illustrates example frequency output of a voltage-controlled oscillator versus time for a selected analog control voltage setting during a digital phase acquisition mode.

FIG. 6 illustrates an example method for triple loop CDR.

FIG. 7 illustrates an example frequency detector.

FIGS. 8A-8C illustrate example inputs and outputs to an example frequency detector.

### DESCRIPTION OF EXAMPLE EMBODIMENTS

Particular embodiments relate to a triple loop CDR architecture. Particular embodiments address the conflict between the generation of VCO noise and the tuning range of the VCO by dividing the VCO control into a digital control portion and an analog control portion. In particular embodiments, the digital control is active only during a digital portion of the frequency acquisition mode in which the CDR attempts to match the VCO clock output from the VCO with the frequency of a reference clock signal and is driven by the digital frequency acquisition loop (first loop). During the time period in which the digital frequency acquisition loop is active, the analog control voltage to the VCO is held constant close to the middle of its operating range (e.g., VDD/2). Once the digital frequency acquisition loop converges, the CDR enters the analog portion of the frequency acquisition mode (second loop), in which the digital VCO control is held constant and the analog VCO control is driven by a frequency detector to further reduce the difference between the frequency of the VCO clock output from the VCO and the reference clock signal. Once the analog frequency acquisition loop converges, the CDR enters the phase acquisition mode (third loop), in which it matches phase with the input data bit stream(s) as opposed to the reference clock signal. The CDR enters phase acquisition mode from the analog frequency acquisition mode when the frequency difference between the VCO clock and the reference clock falls below a certain threshold, which is detected by a frequency comparator. While in the phase acquisition mode, if the frequency difference between the VCO clock and the reference clock becomes larger than a threshold, the CDR assumes loss of frequency and/or phase lock and exits the phase acquisition mode and, in an example embodiment, repeats the lock-in sequence from the start (back to the first digital loop). Particular embodiments enable a CDR to operate with small VCO gain thereby reducing the effect of the noise on the control voltage and VCO jitter on the jitter of the recovered clock and the bit error rate (BER).

Herein, reference to a frequency may encompass a rate, and vice versa, where appropriate. As an example and not by way of limitation, a reference clock frequency may be a reference clock rate, and vice versa, where appropriate. As another example, an input data frequency may be an input data rate, and vice versa, where appropriate.

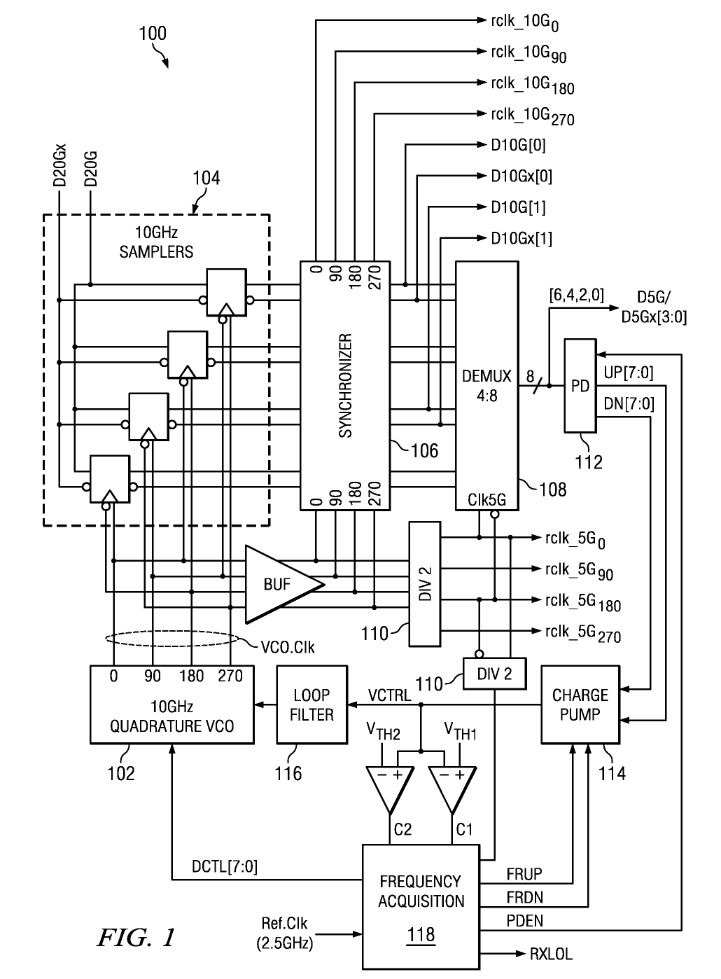

FIG. 1 illustrates an example CDR circuit 100 (CDR 100). In particular embodiments, CDR 100 includes VCO 102, samplers 104, synchronizer 106, demultiplexer (DEMUX) 108, clock dividers 110, phase detector (PD) 112, charge pump (CP) 114, loop filter 116, and frequency acquisition circuit (or block) 118. In a particular example embodiment, VCO 102 is a 10 GHz quadrature VCO based on two coupled LC VCOs and outputs a four phase VCO clock VCO.Clk (e.g., at relative phases of 0°, 90°, 180°, and)270°, samplers 104 include four 10 Gb/s samplers, synchronizer 106 is a 10 Gb/s synchronizer, DEMUX 108 is a 4:8 10 Gb/s to 5 Gb/s DEMUX, clock dividers 110 supply 4-phase 5 GHz clock, and PD 112 and CP 114 operate at 5 Gb/s. In the illustrated embodiment, samplers 104 operate at half data rate and produce four 10 Gb/s sample streams, each synchronous to the VCO phase used to clock the sampler. Synchronizer 106 may serve to synchronize the 10 Gb/s samples to the common reference, which may be, by way of example, VCO phase 0, as well as to generate static 10 Gb/s signals from the outputs of the samplers 104, which may be invalid (reset) half of the cycle. In the illustrated embodiment, the two clock frequency dividers 110 and the DEMUX 108 generate eight 5 Gb/s static CMOS bits from the four 10 Gb/s CML bits from synchronizer 106. PD 112 generates UP and DN signals for CP 114 to adjust the analog control voltage VCTRL generated with loop filter 116 and passed to VCO 102 to raise or lower the frequency of the VCO clock VCO.Clk output from VCO 102, respectively.

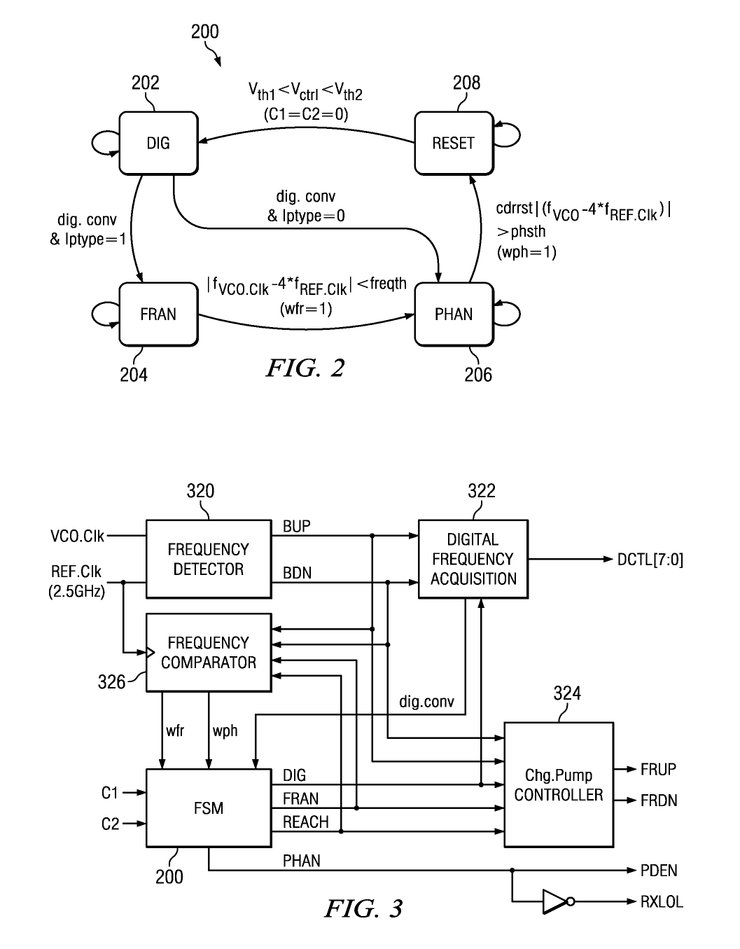

The three operation modes or loops of CDR 100 (digital frequency acquisition, analog frequency acquisition, and phase acquisition), together with an additional initialization mode may be abstracted as the states of CDR 100 and may be implemented as a finite state machine (FSM). FIG. 2 illustrates example states of an example FSM 200. The current state of FSM 200 defines the current mode of operation of CDR 100 and may generate control signals to other elements of CDR 100 as described in more detail below. In particular embodiments, FSM 200 has four core possible states: the DIG state 202, the FRAN state 204, the PHAN state 206, and the RESET state 208, which determine the mode or loop by which CDR 100 operates, as described in more detail below.

In particular embodiments, frequency acquisition block 118 receives as input the VCO clock VCO.Clk output from VCO 102, the reference clock Ref.Clk, and the VCO control voltage VCTRL, and outputs a digital control signal to VCO 102, which, in the illustrated embodiment, is an 8 bit signal DCTL[7:0], during the digital frequency acquisition, state DIG 202. Frequency acquisition block 118 also outputs control signals FRUP and FRDN to CP 114 which are used to adjust the analog voltage VCTRL to raise and lower the frequency of VCO.Clk output by VCO 102, respectively, during the analog frequency acquisition, state FRAN 204. In the illustrated embodiment, frequency acquisition block 118 further outputs the signal PDEN to PD 112, which enables or disables the phase acquisition loop, state PHAN 206. Frequency acquisition block 118 embodies or contains the finite state machine (FSM) 200 of FIG. 2, a frequency detector 320, a digital frequency acquisition block 322, a charge pump (CP) controller 324, and a frequency comparator 326, as illustrated in FIG. 3, as well as any additional logic required to implement the operations described below.

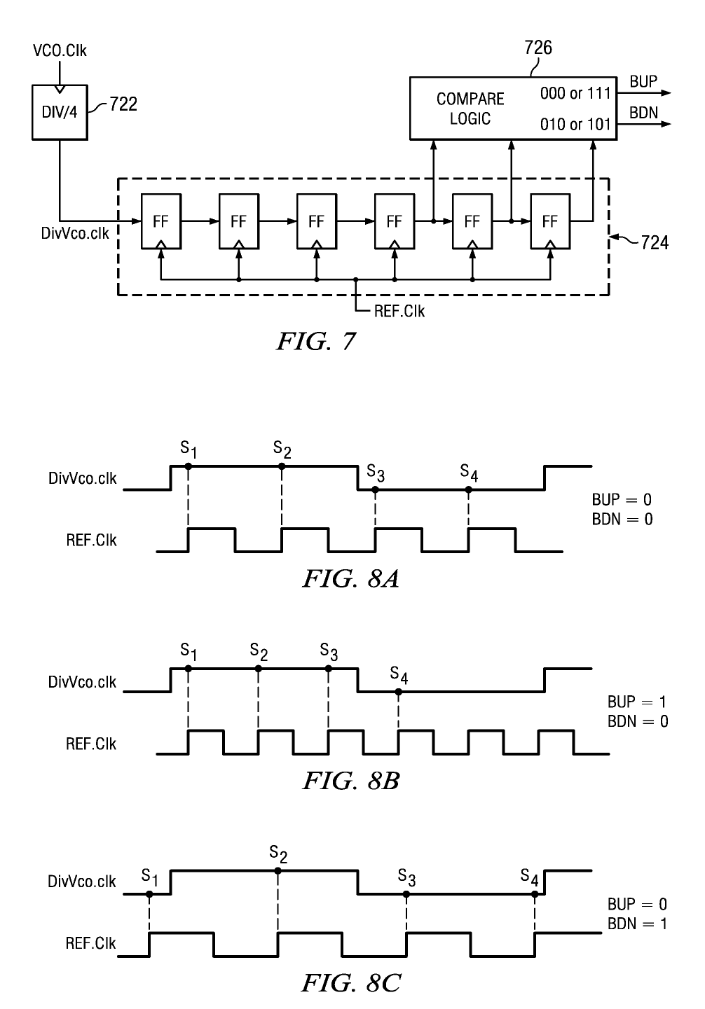

Frequency detector 320 senses the difference between the frequency of VCO.Clk and the frequency of the reference clock Ref.Clk. Frequency detector 320 asserts the digital signal BUP when VCO.Clk is slower than REF.Clk, and asserts the signal BDN when VCO.Clk is faster than REF.Clk. An example frequency detector is described later in the disclosure with reference to FIGS. 7 and 8.

In the illustrated embodiment, frequency comparator 326 asserts the output wfr if the frequency mismatch between VCO.Clk (divided by four) and REF.Clk is less than an externally defined threshold freqth, and asserts the output wph if the frequency mismatch between VCO.Clk (divided by four) and REF.Clk is less than a larger externally defined threshold, phsth. In one example embodiment, the signal wfr is used to control transition from the FRAN state 204 to the PHAN state 206 and is set to zero during the preceding DIG state 202. In one example embodiment, the signal wph is used to control transition from the PHAN state 206 to the RESET state 208, and is set to zero during the preceding DIG and FRAN states 202 and 204. By way of example, external control bits provided by a configuration control circuit such as an I2C bus can be used to set the values of phths and freqth in order to tighten or loosen the criteria for transitioning between the FRAN, PHAN, and RESET states.

In one example embodiment, digital frequency acquisition block 322 includes two cascaded UP/DN counters (an LSB (least significant bit) counter and a MSB (most significant bit) counter), a sequence detector, and a timer. In one example embodiment, both counters are enabled only in the DIG state 202. The UP and DN outputs of the LSB counter drives the MSB counter, the sequence detector, and the timer. The output of the MSB counter is the digital control code DCTL[7:0] for VCO 102. Prior to operation, the MSB counter may be reset so that VCO 102 starts oscillating at the lowest frequency. The sequence detector and the timer circuits may be used to signal the completion or conversion of the digital frequency loop. This event causes FSM 200 to transition from the DIG state 202 to the FRAN state 204.

In one example embodiment, CP controller 324 generates signals FRUP and FRDN for CP 114 based on the current state of FSM 200, or more generally CDR 100, and the signals BUP, BDN, C1, and C2. For purposes of driving CP 114 in the analog frequency acquisition mode (FRAN state 204), signals BUP and BDN may be implemented using a 3-bit saturation counter. This makes the frequency acquisition loop bang-bang type instead of linear, reducing the sensitivity to the charge pump leakage current and shortening the frequency acquisition time. In a particular example embodiment, the signal FRUP is asserted if the state of the saturation counter is above 3 during the FRAN state 204, or when the input C1 is high (e.g., VCTRL<VTH1) in the RESET or DIG states 208 and 202, respectively. In a particular example embodiment, the signal FRDN is asserted if the state of the saturation counter is below 4 during the FRAN state 204, or when the input C2 is high (VCTRL>VTH2) in the RESET or DIG states 208 and 202.

The DIG state 202 of FSM 200 represents the digital frequency acquisition loop. While in this state, the phase acquisition loop is disabled, VCTRL is constant, and CDR 100 uses the output of the frequency detector 320 to set the digital control bits DCTL[7:0] to VCO 102. In an example embodiment, an additional control bit, lptype, can be supplied to bypass the FRAN 204 state. When lptype=1, FSM 200 switches from the DIG state 202 to the FRAN state 204 when the condition(s) for convergence of the digital control loop indicated by signal dig.conv have been met, When lptype=0, FSM 200 switches from the DIG state 202 to the PHAN state 206, bypassing the FRAN state 204, when the condition(s) for convergence of the digital control loop indicated by signal dig.conv have been met.

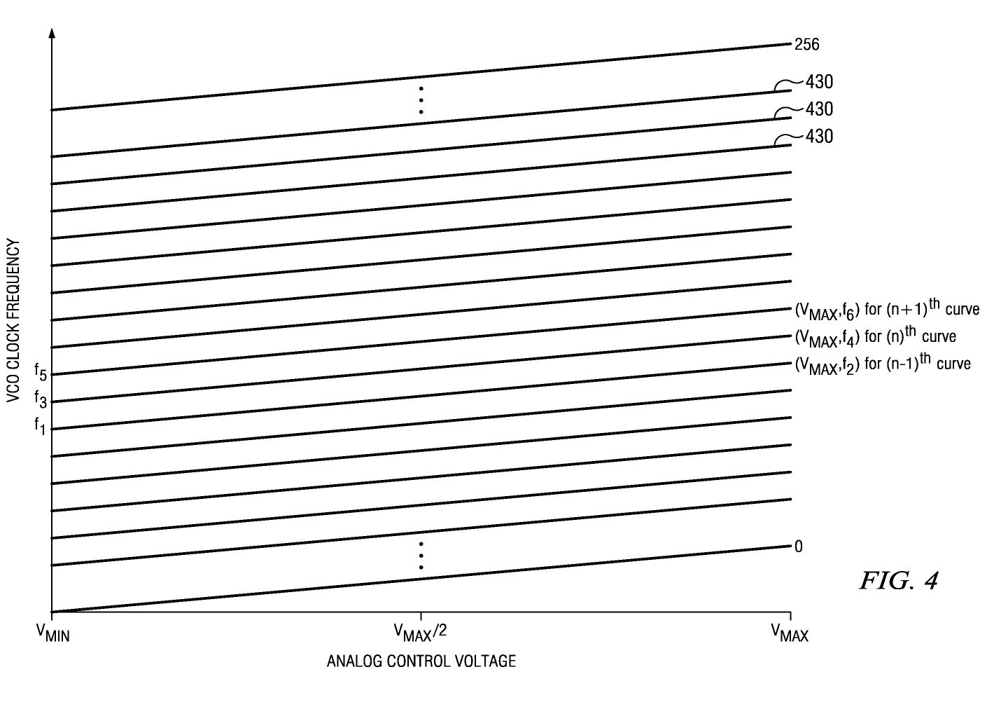

In particular embodiments, the frequency of VCO.Clk output from VCO 102 is a function of both the analog control voltage setting VCTRL and a frequency gain curve determined through digital VCO control DCTL[7:0] as illustrated in FIG. 4 (the slope of each frequency gain curve represents the gain of VCO 102). In the embodiment illustrated in FIG. 4, the clock frequency of VCO.Clk varies linearly with VCTRL, which value may vary from a minimum voltage VMIN, which may be, by way of example, 0 V to a maximum voltage VMAX, which may be, by way of example, VDD. However, the absolute value of the clock frequency of VCO.Clk also depends on the frequency gain curve 430 selected using the digital VCO control DCTL[7:0]. By way of example, if the (n−1)th frequency gain curve 430 is selected, the minimum possible frequency value for VCO.Clk corresponding to VCTRL=VMIN is f1, while the maximum possible frequency value for VCO.Clk corresponding to VCTRL=VMAX is f2. If the nth frequency gain curve 430 is selected, the minimum possible frequency value for VCO.Clk corresponding to VCTRL=VMIN is f3, while the maximum possible frequency value for VCO.Clk corresponding to VCTRL=VMAX is f4. If the (n+1)th frequency gain curve 430 is selected, the minimum possible frequency value for VCO.Clk corresponding to VCTRL=VMIN is f5, while the maximum possible frequency value for VCO.Clk corresponding to VCTRL=VMAX is f6. Depending on the gain of the VCO and the distance between adjacent gain curves 430, the range of possible VCO clock frequencies may overlap between immediately adjacent frequency gain curves in particular embodiments (e.g., f2 is greater than f3). In the illustrated embodiment, there are 256 possible frequency gain curves 430 available for selection corresponding to a digital VCO control DCTL implemented with 8 bits (28=256). In this way, the frequency of VCO.Clk may be finely tuned while also accommodating a wide range of possible reference clock and input data rate frequencies at low gain, thereby significantly reducing VCO noise.

In a particular embodiment, the digital control DCTL[7:0] is used to increment (or decrement, hereinafter incrementing and decrementing are collectively referred to as incrementing) through the frequency gain curves 430 until VCO.Clk is within a threshold of Ref.Clk. By way of example, at the start of the digital frequency acquisition mode, the digital control DCTL[7:0] may start the incrementing from the particular frequency gain curve 430 selected for the immediately preceding digital frequency acquisition mode. As another example, the digital control DCTL[7:0] may start the incrementing from the lowest possible frequency gain curve 430 available or from any other possible frequency gain curve 430 (e.g., highest possible frequency gain curve or midway (e.g., 128th) frequency gain curve). During the incrementing, VCTRL is held constant at a midway voltage such as, by way of example, VDD/2.

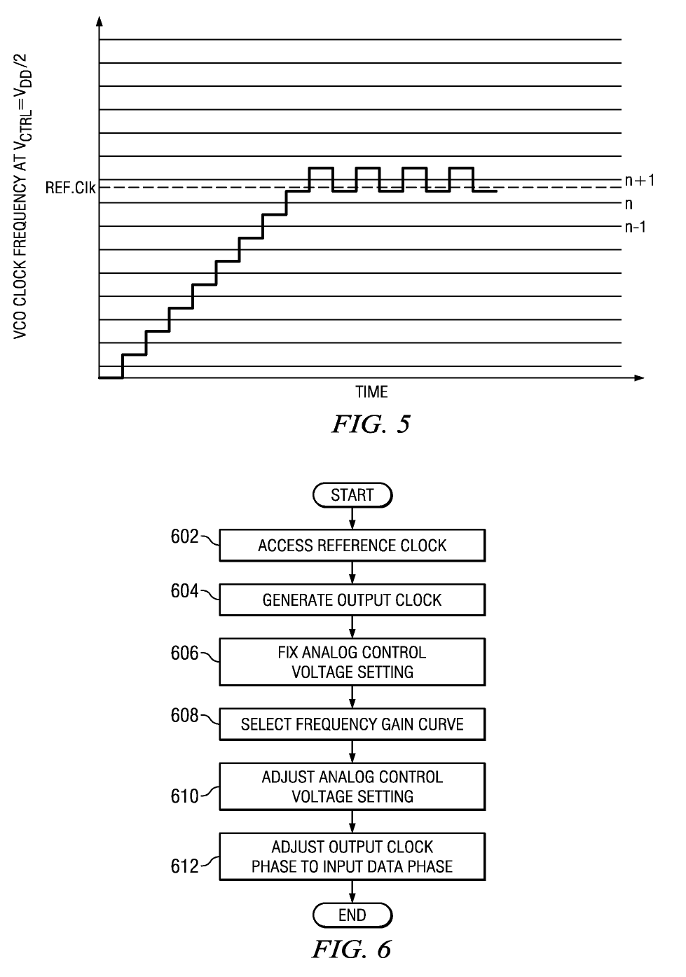

FIG. 5 shows VCO.Clk frequency versus time for VCTRL=VDD/2 during an example incrementing operation. As shown in FIG. 5, by way of example, REF.Clk may be reached via both the nth and (n+1)th frequency gain curves 430 (by adjusting VCTRL up or down relative to VDD/2, respectively, while operating in the subsequent analog frequency acquisition loop). In an example embodiment, once the digital control DCTL[7:0] selects the nth frequency gain curve, it may then select the (n+1)th frequency gain curve in an attempt to bring VCO.Clk closer to REF.Clk; however, upon selecting the (n+1)th frequency gain curve, the system will oscillate between the nth and (n+1)th frequency gain curves because the nth curve produces a VCO frequency lower than the REF.clk frequency when VCTRL=VDD/2 and the (n+1)th curve produces a VCO frequency higher than the REF.clk frequency when VCTRL=VDD/2. Either the nth curve or the (n+1)th curve may be used to reach the REF.Clk frequency in the subsequent FRAN state 204.

In one embodiment, after a predetermined timeout period or after a predetermined number of oscillations have occurred indicating completion or convergence of the digital frequency acquisition loop, one of the two frequency gain curves (n or (n+1)) is selected. By way of example, the condition for convergence may be a toggle back in forth resulting in no change in the digital control code other than oscillating between the nth and (n+1)th frequency gain curves in 216 2.5 GHz cycles (approximately 26 μs). As another example, the condition for convergence may be that the frequency mismatch between VCO.Clk and REF.Clk is less than 200 parts per million (ppm), less than 400 ppm, or less than 800 ppm. In particular embodiments, the gain of each frequency gain curve should be as small as possible to reduce VCO jitter, subject to the constraint that the maximum frequency of the nth curve must exceed the middle frequency of the (n+1)th curve and the minimum frequency of the (n−1)th curve must be lower than the middle frequency of the nth curve. VCO jitter decreases the tolerance of the CDR to data jitter. Furthermore, in particular embodiments, the number of frequency gain curves should be large within limits of memory and implementation to accommodate a wide range of possible reference clock and input data rate frequencies.

In particular embodiments, while operating in the digital frequency acquisition loop, the phase control to the analog control voltage VCTRL through PD 112 and CP 114 is disabled through a signal PDEN that gates the generation of UP and DN signals (which may be implemented with 8 bit control) to CP 114. Additionally, frequency acquisition block 118 updates the digital VCO control DCTL[7:0]. If enabled, such as by setting the external control bit lptype to 1, CDR 100 switches to the analog frequency acquisition loop, FRAN state 204, when the digital control DCTL[7:0] causes VCO.Clk to converge within a predetermined (or predefined) threshold of the reference clock Ref.Clk input to frequency acquisition block 118, which, in the illustrated embodiment, has a frequency of 2.5 GHz. Output dig.conv of the digital frequency acquisition block 322 is set to 1 to indicate convergence. In an alternate embodiment, CDR 100 may switch directly to the phase acquisition loop, PHAN state 206. As described above, convergence of the digital frequency acquisition loop may be demonstrated by oscillating between two immediately adjacent frequency gain curves 430. It will be appreciated that the frequency of the reference clock may vary widely in various embodiments according to many factors including, by way of example, the input data rate.

CDR 100 enters the FRAN state 204 after the digital frequency acquisition (DIG state 202) converges and before the phase acquisition loop (PHAN state 206) if the user selectable external control bit lptype is set to 1. In particular embodiments, upon switching to and operating within the FRAN state 204, frequency acquisition block 118 drives the FRUP and FRDN inputs to CP 114 to attempt to further reduce the difference between the frequencies of VCO.Clk and Ref.Clk. More particularly, the value of the VCO digital control code DCTL[7:0] is unchanged and constant and the output of the frequency detector 320 is transmitted to the FRUP and FRDN inputs to CP 114.

In particular embodiments, CDR 100 switches from the FRAN state 204 to the PHAN state 206 when the mismatch between the frequencies of VCO.Clk and Ref.Clk drops below a predetermined (or predefined) frequency threshold freqth, which may be defined by external control bits. By way of example, if two external control bits are used, a value of 00 may indicate that the VCO output frequency is within 50 ppm of the reference clock Ref.Clk, a value of 01 may indicate that the VCO output frequency is within 100 ppm of the reference clock Ref.Clk, a value of 10 may indicate that the VCO output frequency is within 200 ppm of the reference clock Ref.Clk, and a value of 11 may indicate that the VCO output frequency is within 400 ppm of the reference clock Ref.Clk.

In an example embodiment, while in the phase acquisition loop (PHAN state 206), the frequency acquisition circuit 118 is shut off and a phase locking loop circuit comprising samplers 104, DEMUX 108, PD 112, CP 114, loop filter 116, and VCO 102 is activated. In particular embodiments, CDR 100 only performs clock and data recovery while in the phase acquisition loop. In the illustrated embodiment, only while in the phase acquisition loop CDR 100 deasserts the loss of lock signal RXLOL. While operating in the phase acquisition loop, samplers 104 sample input data bit stream D20G/D20Gx (where “x” denotes that this stream is the complement to the true D20G stream, where together, the D20G/D20Gx streams represent the differential input data signal) at an estimated center and edge of each sampled bit using VCO.Clk. After synchronizing the edge and center samples 106, and, in a sample embodiment, demultiplexing to a lower data rate with DEMUX 108 to facilitate implementation of the phase detector in low-frequency circuits, a phase detector, PD 112, compares the center and edge samples to determine whether the VCO.clk frequency must be retarded or advanced in order to center the clock phases in the data eyes.

Each edge to center sample comparator produces either an UP or a DN signal to charge pump 114. In a sample embodiment with PD 112 operating at ¼th the bit rate, 8 up and 8 down signals are produced at each 5 GHz cycle. While in the PHAN state 206, the frequency monitor continues to compare the mismatch between VCO.Clk output by VCO 102 and Ref.clk. In a particular embodiment, if phase lock is lost during the normal phase acquisition loop operation, CDR 100 is forced back to the frequency acquisition loop through another state, the RESET state 208, in which the analog VCO control voltage VCTRL is brought to, by way of example, VDD/2. By way of example, FSM 200 may switch from the PHAN state 206 to the RESET state 208 when the mismatch between the frequencies of VCO.Clk and Ref.clk exceeds a frequency threshold phsth determined, for example, by one or more external control bits. By way of example, if two external control bits are used, a value of 00 may indicate that VCO.Clk is within 100 ppm of the Ref.clk, a value of 01 may indicate that VCO.Clk is within 200 ppm of Ref.clk, a value of 10 may indicate that VCO.Clk is within 400 ppm of Ref.clk, and a value of 11 may indicate that VCO.Clk is within 800 ppm of Ref.clk.

In particular embodiments, the RESET state 208 is a transition state between the phase acquisition loop and the digital frequency acquisition loop (PHAN state 206 and DIG state 202), during which the VCO control voltage VCTRL is set to a value near VDD/2. The RESET state 208 may also be the state FSM 200 starts with during a reset of CDR 100. While operating in the RESET state 208, CDR 100 compares VCTRL with two threshold voltages, VTH1 and VTH2, selectable, by way of example, from one or more external control bits. By way of example, if two external control bits are used, a value of 10 may specify a VTH1 of 0.25 VDD and a VTH2 of 0.75 VDD, a value of 11 may specify a VTH1 of 0.40 VDD and a VTH2 of 0.60 VDD, a value of 00 may specify a VTH1 of 0.45 VDD and a VTH2 of 0.55 VDD, and a value of 01 may specify a VTH1 of 0.48 VDD and a VTH2 of 0.52 VDD. The outputs of these frequency comparisons are used to control the FRUP and FRDN signals to CP 114 to bring VCTRL between the comparison thresholds. In a particular embodiment, FSM 200 changes state from RESET to DIG when VTH1<VCTRL<VTH2.

FIG. 6 illustrates an example method for triple loop CDR. The method begins at step 602, where a frequency acquisition block accesses a reference clock having a reference clock frequency and reference clock phase. At step 604, a VCO generates an output clock having an output clock phase and output clock frequency that is a function of an analog control voltage setting and a frequency gain curve. At step 606, the frequency acquisition block fixes the analog control voltage setting to a predetermined voltage. At step 608, the frequency acquisition block selects one of the frequency gain curves within a predetermined frequency range of the reference clock frequency at the analog control voltage setting. The frequency acquisition block then adjusts the analog control voltage setting at step 610 to adjust the output clock frequency to be within another predetermined frequency range of the reference clock frequency. At 612, the PLL circuit adjusts the output clock phase to center the sampling edges in the input data stream eyes, at which point the method ends. Particular embodiments may continuously repeat the steps of the method of FIG. 6, according to particular needs. Although the present disclosure describes and illustrates particular steps of the method of FIG. 6 as occurring in a particular order, the present disclosure contemplates any suitable steps of the method of FIG. 6 occurring in any suitable order. Moreover, although the present disclosure describes and illustrates particular components carrying out particular steps of the method of FIG. 6, the present disclosure contemplates any suitable combination of any suitable components carrying out any suitable steps of the method of FIG. 6.

Referring now to FIG. 7, an example frequency detector suitable for use in particular embodiments as frequency detector 320 will be described. In particular embodiments, frequency detector 320 is a digital frequency detector that outputs digitals signals with digital levels and fixed duration (cycle time). In particular embodiments, digital frequency detector 320 may be used to drive the digital circuitry that sets the value of the digital VCO control bits for the digital VCO 102 described above. More particularly, in the illustrated embodiment, frequency detector 320 asserts the digital signal BUP when VCO.Clk is slower than REF.Clk, and asserts the signal BDN when VCO.Clk is faster than REF.Clk.

By way of background, as those of skill in the art will appreciate, conventional frequency detectors in CDR circuits and phase locked loops (PLL) typically operate in the analog domain. Even in the conventional frequency detectors that output digital signals, such as a Phase and Frequency Detector (PFD), these frequency detectors carry the phase information in the analog properties of the signal (e.g., pulse width).

FIG. 7 illustrates an example frequency detector circuit 320. In the illustrated embodiment, frequency detector 320 produces a digital signal whose value is indicative of the frequency difference between a VCO clock, VCO.Clk, and a reference clock, REF.Clk, at its inputs. More particularly, frequency detector 320 outputs fully digital signals BUP and BDN, synchronous with the cycle of either of the compared clocks, such that the difference between the number of cycles in which BUP is active (e.g., logical “1”) and the number of cycles in which BDN is active (e.g., logical “0”) is to a first approximation proportional to the frequency difference between the VCO.Clk and the REF.Clk.

Although the following description focuses on a digital frequency detector 320 in the context of its application in a CDR, such a digital frequency detector has numerous other uses and is not limited to use in a CDR. The principle of operation of the digital frequency detector 320 is based on dividing one of the input clocks and sampling the divided version with the other input clock (using flip-flops clocked using the other clock). By way of example, in the illustrated embodiment, frequency detector 320 includes a clock divider 722, a sampling circuit 724, and compare logic (comparator) 726. In particular embodiments, sampling circuit 724 is implemented with a plurality of flip-flops as shown, by way of example, in FIG. 7. In the illustrated embodiment, VCO.Clk, having a frequency of approximately 2.5 GHz, is input to clock divider 722, which divides VCO.Clk by a divisor of 4 to produce a divided clock DivVCO.Clk, having a frequency of approximately 625 MHz. DivVCO.Clk is then input to a series of flip-flops 724. REF.Clk is also input to the flip-flops 724. In this manner, the divided VCO clock DivVCO.Clk is sampled with the reference clock REF.Clk. The samples are then sent to the compare logic 726, which analyzes patterns in the sequence of samples and produces the signals BUP and BDN.

The number of consecutive samples with the same value indicates the instantaneous frequency difference between DivVCO.Clk and REF.Clk. By way of example, if VCO.Clk is divided by the divisor 4 to produce DivVCO.Clk, and DivVCO.Clk is sampled by the reference clock REF.Clk, then frequency detector 320 will, in the illustrated embodiment, assert BUP (to increase the frequency of VCO.Clk) if it detects a pattern 000 (three consecutive logical zeroes) or a pattern 111 (three consecutive logical ones) in the sequence of samples, and assert BDN (to decrease the frequency of VCO.Clk) if it detects a pattern 101 (one “consecutive” logical zero) or a pattern 010 (one “consecutive” logical one) in the sequence of samples. The difference between the average number of BUP signals and the average number of BDN signals is the indication of the frequency difference between the VCO.Clk and REF.Clk.

FIGS. 8A-8C illustrate example inputs to frequency detector 320 for DivVCO.Clk and REF.Clk and the example resultant digital outputs BUP and BDN output from frequency detector 320. In FIG. 8A, the value of the frequency (e.g., 625 MHz) of DivVCO.Clk is approximately (to at least a first approximation) equal to one-quarter of the value of the frequency (e.g., 2.5 GHz) of REF.Clk, thus, to a first order approximately, VCO.Clk equals REF.Clk and neither signal BUP or BDN is asserted as frequency detector 320 will detect an alternating pattern of two (half the value of the divisor 4) consecutive logical ones followed by two consecutive logical zeroes in the sequence of samples. In FIG. 8B, the value of the frequency of DivVCO.Clk is too slow, thus the signal BUP will be asserted as frequency detector will detect a pattern 101 (one “consecutive” logical zero) or a pattern 010 (one “consecutive” logical one) in the sequence of samples. In FIG. 8C, the value of the frequency of DivVCO.Clk is too fast, thus the signal BDN will be asserted as frequency detector will detect a pattern 101 (one “consecutive” logical zero) or a pattern 010 (one “consecutive” logical one) in the sequence of samples. It should be noted that the frequencies shown in FIGS. 7 and 8 and the clock divider 722 used are simply examples of possible implementations. Furthermore, where and how the one of the input clocks is divided and sampled may be varied.

The BUP and BDN signals may be used to drive a charge pump as in a conventional analog frequency detector, or they can be digitally filtered and processed further to generate a digital VCO control code as described above, facilitating digital PLL loops. In still other embodiments, the BUP and BDN signals may be used in both ways in different modes of a single CDR. Moreover, other variations of the digital frequency detector are conceivable, including different division ratios and interchanging the VCO clock and the reference clock. Furthermore, the frequency detector may be used to detect the difference between any two clocks, not just a VCO clock and a reference clock. Another embodiment involves a digital integration (arithmetic accumulation) of BUP/BDN signals prior to their use in the other parts of the CDR in order to obtain a nonlinear bang-bang frequency detector.

The present disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend.

1. A method comprising:
receiving at a frequency detector a first clock signal and a second clock signal;
dividing at the frequency detector the first clock signal by a value of n to generate a divided first clock signal;
sampling at the frequency detector the divided first clock signal with the second clock signal to generate a plurality of samples;
generating at the frequency detector a first adjustment signal if more than a predetermined number of consecutive samples in a set of consecutive samples have identical logical values; and
generating at the frequency detector a second adjustment signal if less than the predetermined number of consecutive samples in the set of consecutive samples have identical logical values.

2. The method of claim 1, wherein the first clock signal is a Voltage Controlled Oscillator (VCO) clock signal.

3. The method of claim 1, wherein the second clock signal is a reference clock signal.

4. The method of claim 1, wherein the predetermined number of consecutive samples is equal to n/2.

5. The method of claim 1, wherein:
the value of n is 4;
the predetermined number of consecutive samples is 2;
wherein generating the first adjustment signal if more than the predetermined number of consecutive samples in the set of consecutive samples have identical logical values comprises generating the first adjustment signal if more than 2 consecutive samples in the set of consecutive samples have identical logical values;
wherein generating the second adjustment signal if less than the predetermined number of consecutive samples in the set of consecutive samples have identical logical values comprises generating the second adjustment signal if less than 2 consecutive samples in the set of consecutive samples have identical logical values.

6. The method of claim 1, wherein generating the first adjustment signal results in an increase in a frequency of the first clock signal.

7. The method of claim 1, wherein generating the second adjustment signal results in a decrease in a frequency of the first clock signal.

8. The method of claim 1, wherein generating the first adjustment signal results in a decrease in a frequency of the second clock signal.

9. The method of claim 1, wherein generating the second adjustment signal results in an increase in a frequency of the second clock signal.

10. The method of claim 1, further comprising determining a difference between a number of first adjustment signals generated and a number of second adjustment signals generated during a period of time.

11. A circuit comprising:
a clock divider configured to receive a first clock signal and divide the first clock signal by a value of n to generate a divided first clock signal;
a sampling circuit configured to receive a second clock signal and sample the divided first clock signal with the second clock signal to generate a plurality of samples;
a comparator configured to:
generate a first adjustment signal if more than a predetermined number of consecutive samples in a set of consecutive samples have identical logical values; and
generate a second adjustment signal if less than the predetermined number of consecutive samples in the set of consecutive samples have identical logical values.

12. The circuit of claim 11, wherein the first clock signal is a Voltage Controlled Oscillator (VCO) clock signal.

13. The circuit of claim 11, wherein the second clock signal is a reference clock signal.

14. The circuit of claim 11, wherein the predetermined number of consecutive samples is equal to n/2.

15. The circuit of claim 11, wherein:
the value of n is 4;
the predetermined number of consecutive samples is 2;
wherein in order to generate the first adjustment signal if more than the predetermined number of consecutive samples in the set of consecutive samples have identical logical values the comparator is configured to generate the first adjustment signal if more than 2 consecutive samples in the set of consecutive samples have identical logical values;
wherein in order to generate the second adjustment signal if less than the predetermined number of consecutive samples in the set of consecutive samples have identical logical values the comparator is configured to generate the second adjustment signal if less than 2 consecutive samples in the set of consecutive samples have identical logical values.

16. The circuit of claim 11, wherein the first adjustment signal results in an increase in a frequency of the first clock signal.

17. The circuit of claim 11, wherein the second adjustment signal results in a decrease in a frequency of the first clock signal.

18. The circuit of claim 11, wherein the first adjustment signal results in a decrease in a frequency of the second clock signal.

19. The circuit of claim 11, wherein the second adjustment signal results in an increase in a frequency of the second clock signal.

20. The circuit of claim 11, wherein the comparator is further configured to determine a difference between a number of first adjustment signals generated and a number of second adjustment signals generated during a period of time.

21. The circuit of claim 11, wherein the sampling circuit comprises one or more flip-flops.

22. A system comprising:
means for receiving a first clock signal and a second clock signal;
means for dividing the first clock signal by a value of n to generate a divided first clock signal;
means for sampling the divided first clock signal with the second clock signal to generate a plurality of samples;
means for generating a first adjustment signal if more than a predetermined number of consecutive samples in a set of consecutive samples have identical logical values; and
means for generating a second adjustment signal if less than the predetermined number of consecutive samples in the set of consecutive samples have identical logical values.
